(19) United States
(12) Patent Application Publication
(10) Pub. No.: US 2014/0084310 A1
(43) Pub. Date: Mar. 27, 2014

(54) DISPLAY DEVICE AND METHOD FOR MANUFACTURING SAME

(71) Applicant: KABUSHIKI KAISHA TOSHIBA, Tokyo (JP)

(72) Inventors: Kentaro MIURA, Kanagawa-ken (JP); Tomomasa Ueda, Kanagawa-ken (JP); Nobuyoshi Saito, Tokyo (JP); Shintaro Nakano, Kanagawa-ken (JP); Tatsunori Sakano, Kanagawa-ken (JP); Hajime Yamaguchi, Kanagawa-ken (JP)

(73) Assignee: Kabushiki Kaisha Toshiba, Tokyo (JP)

(21) Appl. No.: 13/803,941

(22) Filed: Mar. 14, 2013

(30) Foreign Application Priority Data
Sep. 25, 2012 (JP) 2012-210697

(51) Int. Cl. H01L 33/08

(52) U.S. Cl. CPC H01L 33/08
USPC 257/88; 438/29

(57) ABSTRACT

According to an embodiment, a method for manufacturing a display device, includes steps of disposing a cathode of a first substrate unit to face an anode of a second substrate unit with an intermediate layer interposed, and bonding the cathode to the anode with the intermediate layer interposed. The first substrate unit includes a first substrate, a thin film transistor provided on the first substrate, and the cathode connected to the thin film transistor. The thin film transistor is an n-channel thin film transistor. The second substrate unit includes a second substrate and the anode provided on the second substrate.

### CROSS-REFERENCE TO RELATED APPLICATIONS

This application is based upon and claims the benefit of priority from Japanese Patent Application No. 2012-210697, filed on Sep. 25, 2012; the entire contents of which are incorporated herein by reference.

### FIELD

Embodiments are generally related to a display device and a method for manufacturing the same.

### BACKGROUND

Organic electroluminescence (EL) displays have a wide color gamut and excellent video image display capability and can be used in a wide range of applications such as smartphones, tablet terminals, televisions, etc.

The configuration of an organic EL display is highly unrestricted. For example, a flexible display device can be realized by forming thin film transistors (TFTs) and an organic EL layer on a substrate with a resin layer interposed and by removing the substrate.

However, technology to prevent the organic EL layer from contacting water and oxygen is important because the organic EL layer degrades when reacting with water and oxygen. Also, there are cases where the luminance of the organic EL display decreases due to the degradation of the organic EL layer and the change of the drive circuit over time.

### BRIEF DESCRIPTION OF THE DRAWINGS

FIG. 1 is a schematic cross-sectional view illustrating a display device according to a first embodiment;

FIG. 2A is an equivalent circuit showing the display device according to the first embodiment, and FIG. 2B is an equivalent circuit of a display device according to a comparative example;

FIGS. 3A to 4 are schematic cross-sectional views showing a method for manufacturing the display device according to the first embodiment;

FIGS. 5A to 5C are schematic plan views showing a portion of the display device according to the first embodiment;

FIGS. 6A and 6B are schematic cross-sectional views showing a portion of the display device according to the first embodiment;

FIG. 7 is a schematic cross-sectional view showing a method for manufacturing the display device according to a first variation of the first embodiment;

FIG. 8 is a schematic cross-sectional view showing a method for manufacturing the display device according to a second variation of the first embodiment;

FIG. 9 is a schematic cross-sectional view showing a method for manufacturing the display device according to a third variation of the first embodiment;

FIG. 10 is a schematic cross-sectional view showing a method for manufacturing the display device according to a fourth variation of the first embodiment;

FIG. 11 is a schematic cross-sectional view showing a method for manufacturing the display device according to a fifth variation of the first embodiment;

FIG. 12 is a schematic cross-sectional view showing a method for manufacturing the display device according to a sixth variation of the first embodiment;

FIG. 13 is a schematic cross-sectional view showing a method for manufacturing the display device according to a seventh variation of the first embodiment;

FIG. 14 is a schematic cross-sectional view illustrating a display device according to a second embodiment;

FIGS. 15A and 15B are schematic plan views showing a portion of the display device according to the second embodiment;

FIGS. 16A to 16C are schematic cross-sectional views showing a method for manufacturing a display device according to a third embodiment;

FIGS. 17A to 17C are schematic cross-sectional views showing a method for manufacturing the display device according to a first variation of the third embodiment;

FIGS. 18A to 18C are schematic cross-sectional views showing a method for manufacturing the display device according to a second variation of the third embodiment;

FIGS. 19A to 19C are schematic cross-sectional views showing a method for manufacturing the display device according to a third variation of the third embodiment; and

FIGS. 20A to 20E are schematic cross-sectional views showing a portion of a display device according to a fourth embodiment.

### DETAILED DESCRIPTION

According to an embodiment, a method for manufacturing a display device, includes steps of disposing a cathode of a first substrate unit to face an anode of a second substrate unit with an intermediate layer interposed, and bonding the cathode to the anode with the intermediate layer interposed. The first substrate unit includes a first substrate, a thin film transistor provided on the first substrate, and the cathode connected to the thin film transistor. The thin film transistor is an n-channel thin film transistor. The second substrate unit includes a second substrate and the anode provided on the second substrate.

According to another embodiment, a display device includes an anode, an intermediate layer, a cathode and a thin film transistor. The intermediate layer includes a hole transport layer, a light emitting layer, and an electron transport layer, and the light emitting layer is provided between the hole transport layer and the electron transport layer. The cathode is bonded to the anode with the intermediate layer interposed; and the thin film transistor connected to the cathode, the thin film transistor being an n-channel thin film transistor.

Embodiments will now be described with reference to the drawings. The drawings are schematic or conceptual; and the relationships between the thicknesses and the widths of portions, the proportional coefficients of sizes between portions, etc., are not necessarily the same as the actual values thereof. Further, the dimensions and/or the proportional coefficients may be illustrated differently between the drawings, even for identical portions.

In the drawings and the specification of the application, components similar to those described in regard to a drawing thereinabove are marked with like reference numerals, and a detailed description is omitted as appropriate.

### First Embodiment

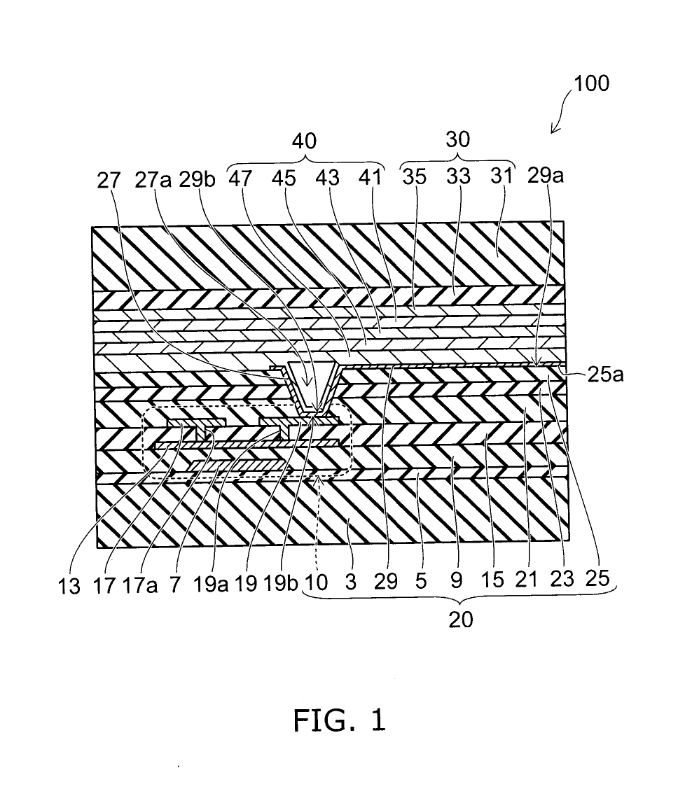

FIG. 1 is a schematic cross-sectional view showing a display device according to a first embodiment.

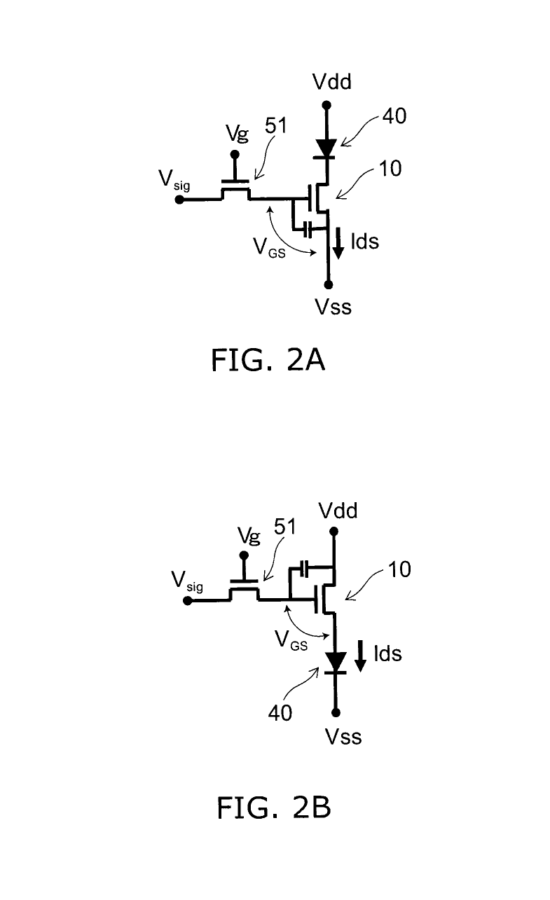

FIG. 2A is an equivalent circuit showing the display device according to the first embodiment.

FIG. 2B is an equivalent circuit of a display device according to a comparative example.

As shown in FIG. 1, the display device 100 according to the embodiment includes a first substrate unit 20, a second substrate unit 30, and an intermediate layer 40.

The first substrate unit 20 includes a first substrate 3, an n-channel thin film transistor 10 provided on the first substrate, and a cathode 29 connected to the thin film transistor 10.

The second substrate unit 30 includes a second substrate 31, and an anode 35 provided on the second substrate.

In the manufacturing process of the display device 100, the first substrate unit 20 is caused to oppose the second substrate unit 30 with the intermediate layer 40 interposed. Then, the first substrate unit 20 is bonded to the second substrate unit 30 with the intermediate layer 40 interposed between the cathode 29 and the anode 35.

A configuration example of the components will now be described with reference to FIG. 1.

The first substrate unit 20 includes the first substrate 3, an undercoat layer 5, the thin film transistor 10, a color filter (CF) layer 23, a planarizing layer 25, and the cathode 29.

The thin film transistor 10 includes a gate electrode 7, a gate insulating film 9, a channel layer 13, a source electrode 17, and a drain electrode 19.

The gate electrode 7 is provided selectively on the undercoat layer 5. The gate insulating film 9 is provided on the undercoat layer 5 to cover the gate electrode 7.

The channel layer 13 opposes the gate electrode 7 which is selectively provided on the gate insulating film 9. A channel protection layer 15 is provided on the gate insulating film 9 to cover the channel layer 13.

The source electrode 17 is provided on the channel protection layer 15 and is electrically connected to the channel layer 13 via a contact hole 17a made in the channel protection layer 15.

The drain electrode 19 also is provided on the channel protection layer 15 and is electrically connected to the channel layer 13 via a contact hole 19a made in the channel protection layer 15.

A protective layer 21, the color filter layer 23, and the planarizing layer 25 are stacked in order on the channel protection layer 15. To protect the thin film transistor 10, the protective layer 21 covers the thin film transistor 10 except for a drain contact portion 19b of the drain electrode 19.

The cathode 29 is provided selectively on the planarizing layer 25. The cathode 29 is electrically connected to the thin film transistor 10 via a contact hole 27 that communicates with the drain contact portion 19b from an upper surface 25a of the planarizing layer 25. In other words, the cathode 29 has a first portion 29a that contacts the intermediate layer 40, and a second portion 29b that contacts the drain contact portion 19b via the contact hole 27.

The intermediate layer 40 includes at least a light emitting layer 45; and the light emitting layer 45 emits light having a component of a wavelength of visible light. The light emitting layer 45 is, for example, an organic layer including an organic light-emitting material. In the embodiment, the intermediate layer 40 includes a hole injection layer 41, a hole transport layer 43, the light emitting layer 45, and an electron transport layer 47. The light emitting layer 45 is provided between the hole transport layer and the electron transport layer. The cathode 29 contacts the electron transport layer 47 at the first portion 29a.

The second substrate unit 30 includes the second substrate 31, a reflecting electrode 33, and the anode 35. The anode 35 contacts the hole injection layer 41 of the intermediate layer 40.

Holes are injected from the anode 35 into the intermediate layer 40; and electrons are injected from the cathode 29 into the intermediate layer 40. The holes reaching the light emitting layer 45 via the hole injection layer 41 and the hole transport layer 43 undergo radiative recombination with the electrons reaching the light emitting layer 45 via the electron transport layer 47. Thereby, light is radiated from the intermediate layer 40.

In the embodiment, the light that is radiated in the direction of the second substrate unit 30 is reflected toward the direction of the first substrate unit 20 by the reflecting electrode 33. In other words, the display surface of the display device 100 is on the first substrate unit 20 side.

By the reflecting electrode 33 including a metal having excellent barrier properties to moisture and oxygen, it is possible to effectively suppress the penetration of water or oxygen through the second substrate unit 30 to the intermediate layer 40, i.e., the light emitting layer, the electron injection layer, and the hole injection layer, and to the region between the electrode and the intermediate layer 40.

Between the first substrate unit 20 and the intermediate layer 40, the spacing between the light emitting layer 45 and the first portion 29a of the cathode 29 is less than the spacing between the light emitting layer 45 and the second portion 29b of the cathode 29. A space 27a that includes a gas is included between the second portion 29b and the light emitting layer 45. Water entering the intermediate layer 40 can be reduced by trapping moisture in the space 27a.

Thus, in the embodiment, it is possible to suppress the degradation of the intermediate layer 40 caused by water, oxygen, etc., of the external environment; and the reliability of the display device 100 can be increased.

In the embodiment, the cathode 29 is connected to the drain side of the thin film transistor 10. Therefore, the equivalent circuit of one pixel of the display device 100 has the configuration shown in FIG. 2A. Namely, the intermediate layer 40 is connected in series to the thin film transistor 10 that drives the pixel; and a drive current I_{ds} flows from the intermediate layer 40 into the thin film transistor 10. A signal voltage V_{sig} is supplied to the gate of the thin film transistor 10 via a write transistor 51.

By such a circuit configuration, the luminance change due to the degradation of the intermediate layer 40 can be suppressed. For example, a voltage V_{GS} between the gate-source does not change even when the resistance of the intermediate layer 40 changes and the drain voltage of the thin film transistor 10 changes. Therefore, the change of the drive current I_{ds} flowing in the intermediate layer 40 can be suppressed to being only the fluctuation caused by the degradation of the intermediate layer 40.

Conversely, in the equivalent circuit according to the comparative example shown in FIG. 2B, the intermediate layer 40 is connected to the source side of the thin film transistor 10. The drive current I_{ds} flows from the thin film transistor 10 side into the intermediate layer 40. When the resistance of the intermediate layer 40 changes, the source voltage of the thin film transistor 10 changes; and the voltage V_{GS} between the gate-source changes. Therefore, the fluctuation of the drive current I_{ds} increases not only due to the degradation of the intermediate layer 40 but also due to the fluctuation of the operating point of the transistor due to the change of the gate voltage. In other words, the luminance change of the intermediate layer 40 is amplified. Moreover, a high breakdown voltage driver is necessary because the voltage V_{sig} is the sum of the voltage V_{GS} between the gate-source and a voltage V_{OLED} consumed in the intermediate layer 40, which results in high costs and high power consumption.

Thus, in the embodiment, the luminance change due to the characteristic degradation of the intermediate layer 40 can be suppressed by connecting the cathode side of the intermediate layer 40 to the drain of the thin film transistor 10; and the costs and power consumption can be reduced.

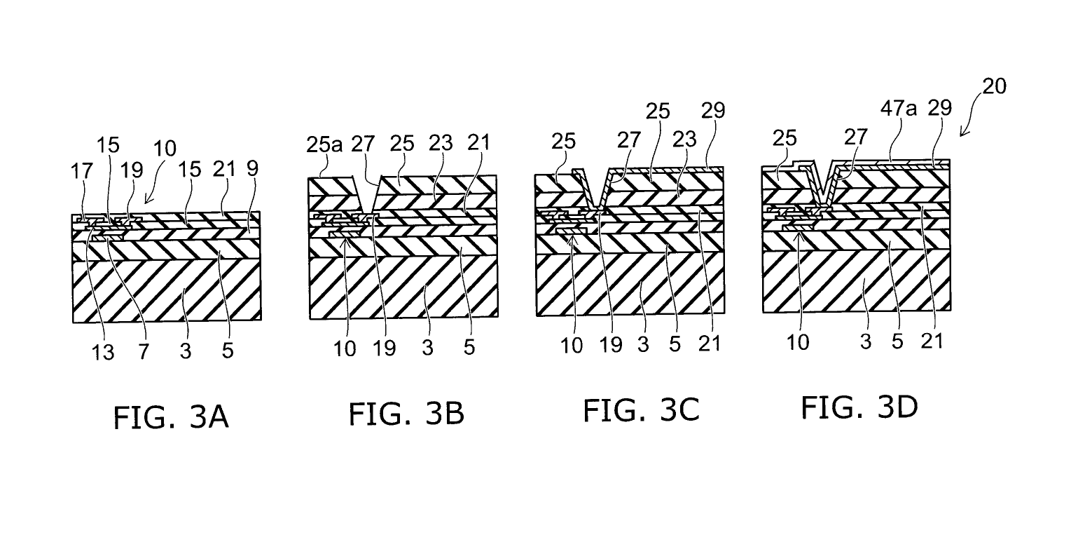

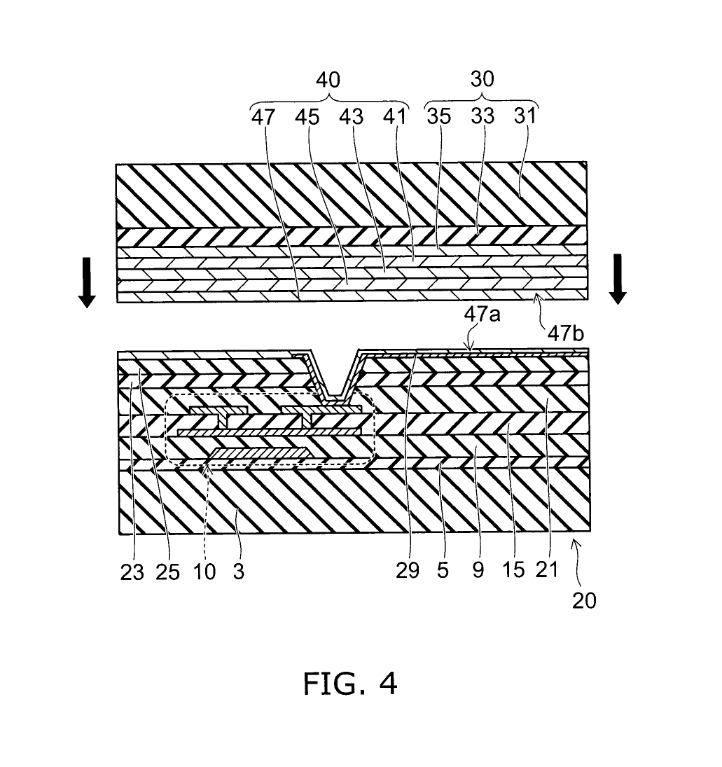

FIG. 3A to FIG. 3D and FIG. 4 are schematic cross-sectional views showing the method for manufacturing the display device 100 according to the first embodiment.

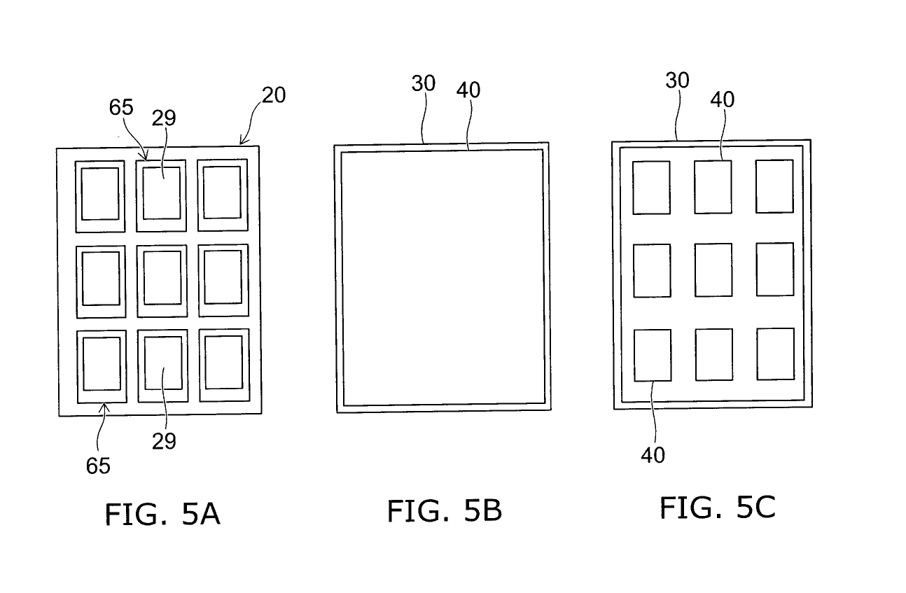

FIG. 5A and FIG. 5C are schematic plan views showing a portion of the display device 100 according to the first embodiment.

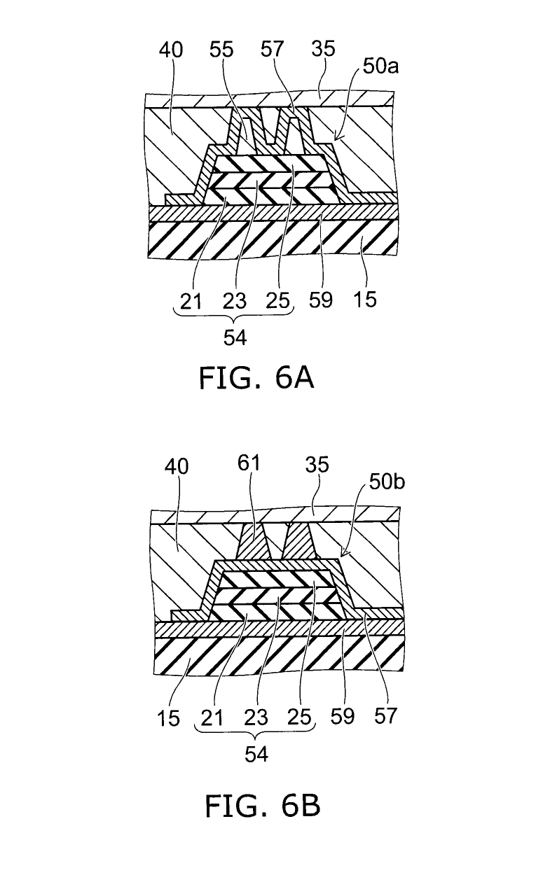

FIG. 6A and FIG. 6B are schematic cross-sectional views showing a portion of the display device 100 according to the first embodiment.

FIG. 3A to FIG. 3D are schematic cross-sectional views showing manufacturing processes of the first substrate unit 20.

First, as shown in FIG. 3A, the undercoat layer 5 is formed on the first substrate 3. The first substrate 3 may include, for example, a material that is light-transmissive such as alkali-free glass, etc. Quartz glass and soda-lime glass also are usable. An insulating material such as, for example, a silicon oxide film, a silicon nitride film, a silicon oxynitride film, etc., may be used as the undercoat layer 5. Also, a stacked film of a silicon oxide film and a silicon nitride film may be used. Such films may be formed by, for example, plasma CVD (Chemical Vapor Deposition). The thickness of the undercoat layer 5 is, for example, about 200 nanometers (nm).

Then, the thin film transistor 10 is formed. Although the thin film transistor 10 shown in the example is an amorphous silicon TFT having a bottom-gate structure, this is not limited thereto. As described below, other materials and structures may be used.

A metal thin film is formed on the entire surface of the undercoat layer 5 by, for example, sputtering. Continuing, a resist mask is formed by photolithography; and the gate electrode 7 and interconnects such as the gate line, etc., are patterned. The metal thin film is a single layer or stacked film of titanium (Ti), tantalum (Ta), molybdenum (Mo), tungsten (W), aluminum (Al), copper (Cu), or silver (Ag), or an alloy of these metals.

Then, the gate insulating film 9, the channel layer 13, and the channel protection layer 15 are formed continuously on the undercoat layer 5 where the gate electrode 7 and the not-shown interconnect are formed.

The gate insulating film 9 is, for example, an insulative material such as a silicon nitride film, a silicon oxide film, a silicon oxynitride film, etc. The thickness of the gate insulating film is, for example, in the range of 50 to 500 nm.

The channel layer 13 may include, for example, an oxide semiconductor layer such as IGZO (InGaZnO), ITO (Indium Tin Oxide), ITZO (InSnZnO), IZO (InZnO), ZnO, etc.

The channel protection layer 15 is, for example, a silicon oxide film, a silicon nitride film, or a silicon oxynitride film that is formed with a thickness in the range of 50 to 500 nm.

Then, the channel layer 13 and the channel protection layer 15 are patterned into a prescribed configuration; and the source electrode 17 and the drain electrode 19 are formed to contact the channel layer 13. The source electrode 17 and the drain electrode 19 are formed of a material that is conductive. The source electrode 17 and the drain electrode 19 also may be formed by stacking two or more types of conductive materials. Then, the protective layer 21 is formed to cover the source electrode 17, the drain electrode 19, and the channel protection layer 15.

The protective layer 21 is, for example, a silicon oxide film or an insulative material that includes a silicon nitride film, a silicon oxynitride film, or an aluminum oxide film. The thickness of the protective layer 21 is formed to be in the range of 50 to 500 nm.

The channel layer 13 may include, for example, a hydrogenated amorphous silicon layer. In such a case, phosphorus-doped hydrogenated amorphous silicon (n⁺ a-Si:H) is formed as an n⁺ layer between the channel layer 13 and the source electrode and between the channel layer 13 and the drain electrode. The n⁺ layer may be patterned simultaneously with the etching of the channel layer 13.

It is also possible to make a contact hole in the gate insulating film 9 and form the gate interconnect from the same metal as that of the source/drain electrodes.

Then, as shown in FIG. 3B, the color filter layer 23 and the planarizing layer 25 are formed on the protective layer 21. For example, color resists of RGB are patterned by photolithography. The color filter layer 23 is, for example, an acrylic resin and is formed with a thickness of 500 to 5000 nm. In the case of a monochrome display, a configuration in which the color filter layer 23 is not formed may be used.

Multiple pixels 65 are provided on the first substrate unit 20; and the thin film transistor 10 and the cathode 29 are provided for each pixel. To reduce the power consumption, four subpixels of RGBW may be formed. A transparent resin layer may be formed as the color filter layer 23 at the W pixel.

Continuing, the planarizing layer 25 is formed. The planarizing layer 25 may include, for example, a photosensitive resin such as acrylic, polyimide, etc. The planarizing layer 25 is formed with a thickness of, for example, 500 to 5000 nm. Then, the contact hole 27 is made to communicate with the drain electrode 19 of the thin film transistor 10 from the upper surface 25a of the planarizing layer 25.

Structures are possible in which the stacking order of the planarizing layer 25 and the color filter layer 23 is reversed or the planarizing layer 25 is not provided.

Then, as shown in FIG. 3C, the cathode 29 is formed on the planarizing layer 25 and on the inner surface of the contact hole 27. The cathode 29 is formed for each pixel 65. It is favorable for a method for manufacturing that suppresses the oxidization of the surface of the cathode 29 to be used as described below when patterning the cathode 29.

The cathode 29 may include, for example, a conductive material such as magnesium-silver alloy (MgAg), aluminum (Al), silver (Ag), etc. In the embodiment, the light of the intermediate layer 40 is extracted to the outside through the cathode 29 because the display surface is provided on the first substrate unit 20 side. Accordingly, it is desirable for the film thickness of the cathode 29 to be thin, e.g., not more than 20 nm. An injection layer of lithium fluoride (LiF), cesium fluoride (CsF), etc., may be formed on the cathode 29 to increase the injection efficiency of the carriers.

Then, as shown in FIG. 3D, a portion 47a of the electron transport layer 47 is formed on the cathode 29 and on the planarizing layer 25. The electron transport layer 47 can be formed by, for example, vacuum vapor deposition.

Continuing as shown in FIG. 4, the first substrate unit 20 is caused to oppose the second substrate unit 30 with the intermediate layer 40 interposed; and the second substrate unit 30 is bonded to the first substrate unit 20.

The second substrate unit 30 includes the second substrate 31, the reflecting electrode 33, and the anode 35. The material of the second substrate 31 may include, for example, an insulating material such as plastic, glass, etc., or stainless steel (SUS), etc. The reflecting electrode 33 is formed on the second substrate 31 by, for example, sputtering. The reflecting electrode 33 may include, for example, a light-reflective material having a high reflectance such as aluminum, silver, etc. An aluminum foil or a silver foil may be adhered.

In the case where the light is extracted from the second substrate 31 side, a configuration may be used in which the reflecting electrode 33 is formed locally or the reflecting electrode 33 is not formed.

A barrier layer may be formed between the second substrate 31 and the reflecting electrode 33. The barrier layer may include, for example, a single-layer or a stacked film including two or more insulating materials of a silicon nitride film, a silicon oxide film, a silicon oxynitride film, acrylic, epoxy, aluminum oxide, parylene, etc.

Continuing, the anode 35 is formed on the reflecting electrode 33. The anode 35 is, for example, a conductive material such as an ITO film, etc. The ITO film may be formed by, for example, sputtering. It is favorable to perform processing of the surface of the ITO film using oxygen plasma. Thereby, the injection efficiency of the carriers from the anode 35 into the intermediate layer 40 can be increased; and the luminous efficiency of the intermediate layer 40 can be increased.

In the embodiment, the intermediate layer 40 is formed on the anode 35. In other words, the intermediate layer 40 includes the hole injection layer 41, the hole transport layer 43, the light emitting layer 45, and the electron transport layer 47 which are formed in order on the anode 35 by, for example, vacuum vapor deposition.

As shown in FIG. 5A, multiple display regions (29 in the drawing) may be formed on the first substrate unit 20. The intermediate layer 40 may be formed on the entire surface of the second substrate unit 30 as shown in FIG. 5B and it may be possible to form the intermediate layer 40 so as to match the pixels 65 as shown in FIG. 5C. In the case of FIG. 5B, the manufacturing is easier because it is unnecessary to align the pixels 65 provided in the first substrate unit 20 with the second substrate on which the intermediate layer 40 is formed.

Then, the first substrate unit 20 and the second substrate unit 30 are bonded with the intermediate layer 40 interposed. It is favorable for this process to be performed in a vacuum such that bubbles, etc., do not remain at the bonding interface. Specifically, the first substrate unit 20 is heated to 80° C. to 130° C.; the portion 47a of the electron transport layer 47 provided on the first substrate unit 20 is caused to contact the one other portion 47b of the electron transport layer 47 provided on the second substrate unit 30; and bonding is performed by adding pressure. Thereby, the bonding structure in which the intermediate layer 40 is interposed between the cathode 29 and the anode 35 is completed.

Other than using carbon or silver (Ag) paste as the connection unit between the anode 35 and the interconnect of the first substrate unit 20, methods such as those shown in FIG. 6A and FIG. 6B also are possible.

As shown in FIG. 6A, a connection unit 50a includes, for example, a base 54 and a protrusion 55 provided on the base 54, where the base 54 is formed by patterning the protective layer 21, the color filter layer 23, and the planarizing layer 25. The protrusion 55 is formed of, for example, an acrylic resin or polyimide that is photosensitive. A conductive layer 57 is provided on the surfaces of the protrusion 55 and the base 54.

As in a connection unit 50b shown in FIG. 6B, a protrusion 61 may be provided on the base 54 by using a conductive resin or a metal paste.

The connection units 50a and 50b are provided in the first substrate unit 20. Then, when bonding the first substrate unit 20 and the second substrate unit 30, the protrusion 55 or the protrusion 61 pierces the intermediate layer 40; and the tip of the protrusion 55 or the protrusion 61 contacts the anode 35. Thereby, for example, a power supply line 59 provided on the channel protection layer 15 can be electrically connected to the anode 35.

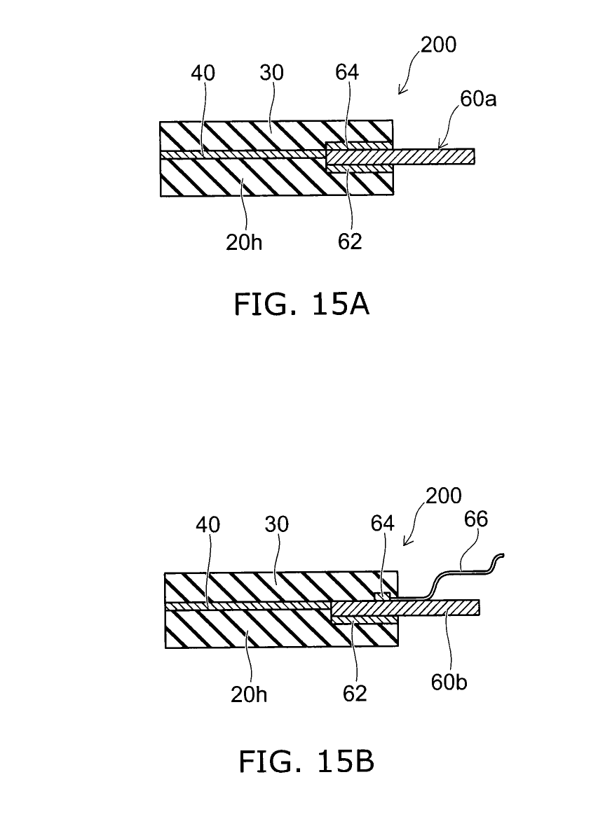

It is also possible to input a signal from the outside to the anode as shown in FIG. 15A and FIG. 15B.

As shown in FIG. 15A, a connection unit 60a is, for example, a flexible printed circuit board (FPC) including an ACF (Anisotropic Conductive Film) 62 on the surface connected to a first substrate unit 20h; and a conductive resin 64 is provided on the surface connected to the second substrate unit 30.

As in a connection unit 60b shown in FIG. 15B, an external connection interconnect 66 may be linked to the conductive resin 64.

The display device 100 shown in FIG. 1 can be constructed by the processes recited above. The contact hole 27 between the intermediate layer 40 and the first substrate unit remains as a space including a gas.

In the embodiment, the intermediate layer 40 is formed on the second substrate unit 30. It is possible to use a plastic substrate as the second substrate 31 because patterning of the intermediate layer 40 is unnecessary. The problem of shifting does not occur even in the case where expansion and contraction of the plastic substrate occur when bonding the second substrate unit 30 and the first substrate unit 20; and a high definition display can be realized.

In the manufacturing processes recited above, it is unnecessary for a thin film sealing layer to be provided after the formation of the intermediate layer 40, which leads to fewer processes. The sealing performance improves because it is unnecessary to limit the film formation temperature during the barrier layer formation to be not more than the tolerable temperature of the intermediate layer 40.

Providing the reflecting electrode 33 not only increases the light extraction efficiency from the intermediate layer 40 but also increases the sealing effect of the intermediate layer 40 and makes it possible to extend the life.

If a flexible material such as plastic, thin glass, etc., is used as the second substrate 31, it is possible to employ a roll to roll manufacturing process; the material usage efficiency can be increased; and the manufacturing cost can be reduced.

Although the portion 47b of the electron transport layer 47 provided on the second substrate unit 30 is bonded to the portion 47a of the electron transport layer 47 provided on the first substrate unit 20 in the embodiment, other layers of the intermediate layer 40 may be bonded to each other.

Although the hole injection layer 41, the hole transport layer 43, and the electron transport layer 47 are provided in addition to the light emitting layer 45 in the intermediate layer 40 in the embodiment, these layers are provided arbitrarily. The intermediate layer 40 may include an electron injection layer.

In other words, the intermediate layer includes a first layer and the light emitting layer. The light emitting layer and a portion of the first layer are provided on the cathode, and one other portion of the first layer is provided on the anode; or, the portion of the first layer is provided on the cathode, and the light emitting layer and the one other portion of the first layer are provided on the anode. The cathode and the anode are bonded with the intermediate layer interposed by connecting the portion of the first layer and the one other portion of the first layer to each other.

Or, the entire intermediate layer may be provided on the cathode; and the anode may be bonded with the intermediate layer interposed.

Or, the entire intermediate layer may be provided on the anode; and the cathode may be bonded with the intermediate layer interposed.

The layers of the intermediate layer 40 other than the light emitting layer 45 may be formed of organic materials or inorganic materials. A layer formed of an organic material is easier to bond than a layer formed of an inorganic material.

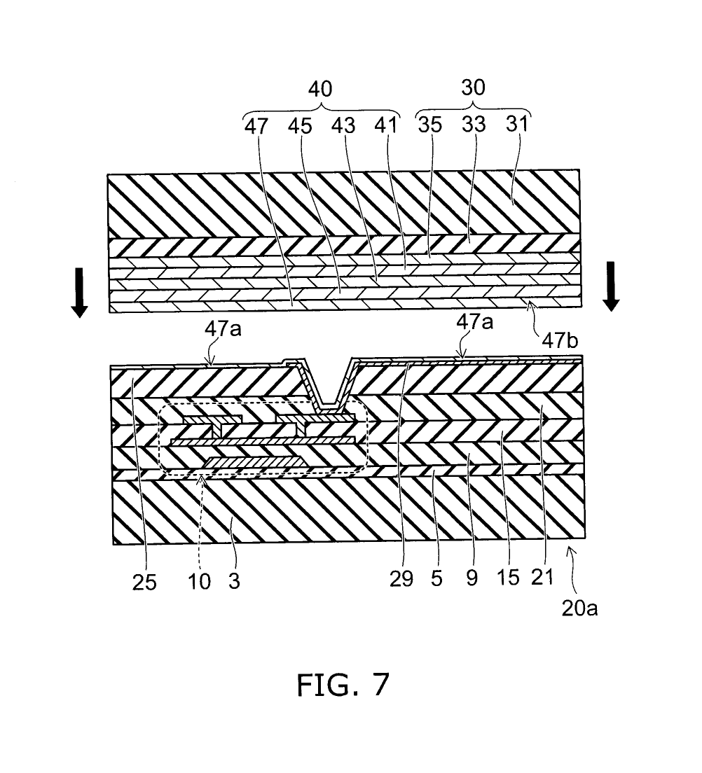

FIG. 7 is a schematic cross-sectional view showing a method for manufacturing the display device according to a first modification of the first embodiment. In this modification, a first substrate unit 20a does not include the color filter layer 23. The planarizing layer 25 is provided directly on the protective layer 21 covering the thin film transistor 10. The intermediate layer 40 is provided on the anode 35 of the second substrate unit 30. The first substrate unit 20 and the second substrate unit 30 are bonded by causing the portion 47a of the electron transport layer 47 provided on the first substrate unit 20 to contact the one other portion 47b of the electron transport layer provided on the second substrate unit 30 side. For example, such a configuration may be used in a monochrome display device.

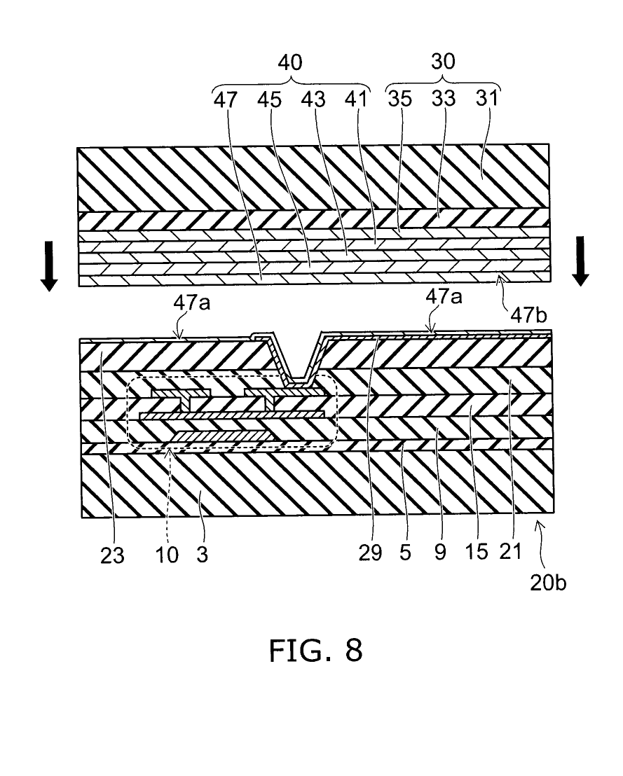

FIG. 8 is a schematic cross-sectional view showing a method for manufacturing the display device according to a second modification of the first embodiment. In this modification, a first substrate unit 20b does not include the planarizing layer 25. The cathode 29 is provided directly on the color filter layer 23. The intermediate layer 40 is provided on the anode 35 of the second substrate unit 30. The first substrate unit 20 and the second substrate unit 30 are bonded by causing the portion 47a of the electron transport layer 47 provided on the first substrate unit 20 to contact the one other portion 47b of the electron transport layer provided on the second substrate unit 30 side.

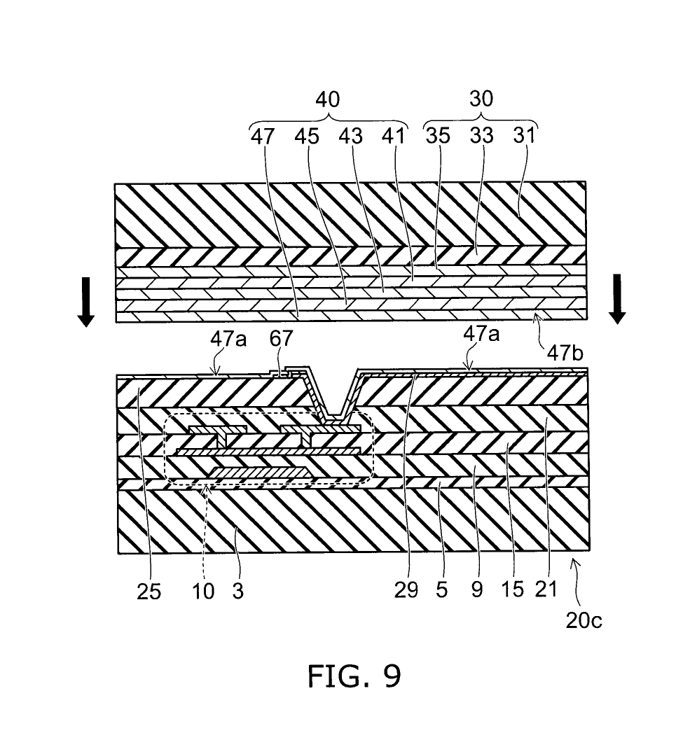

FIG. 9 is a schematic cross-sectional view showing a method for manufacturing the display device according to a third modification of the first embodiment. In this modification, a protective film 67 is provided at the end of the cathode 29. The protective film 67 may include, for example, an insulating film such as a polyimide film, an acrylic resin, a silicon oxide film, a silicon nitride film, etc. By providing the protective film 67, it is possible to prevent shorts between the cathode 29 and the anode 35 caused by the cathode end.

The intermediate layer 40 is provided on the anode 35 of the second substrate unit 30. The first substrate unit 20 and the second substrate unit 30 are bonded by causing the portion 47a of the electron transport layer 47 provided on the first substrate unit 20 to contact the one other portion 47b of the electron transport layer provided on the second substrate unit 30 side.

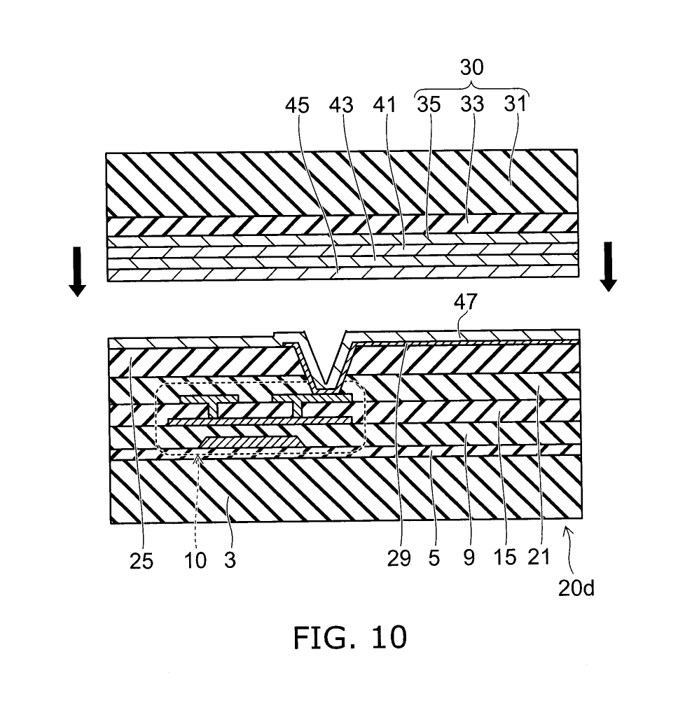

FIG. 10 is a schematic cross-sectional view showing a method for manufacturing the display device according to a fourth modification of the first embodiment. In this modification, the hole injection layer 41, the hole transport layer 43, and the light emitting layer 45 of the intermediate layer 40 are provided on the anode 35. On the other hand, the electron transport layer 47 is provided on the cathode 29 and the planarizing layer 25 of the first substrate unit 20. The first substrate unit 20 and the second substrate unit 30 are bonded by causing the electron transport layer 47 provided on the first substrate unit 20 to contact the light emitting layer 45 provided on the second substrate unit 30 side.

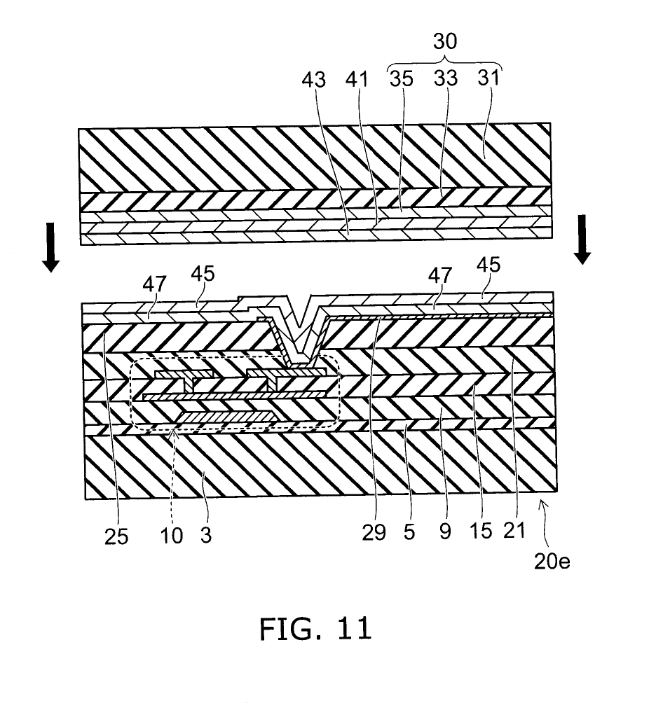

FIG. 11 is a schematic cross-sectional view showing a method for manufacturing the display device according to a fifth modification of the first embodiment. In this modification, the hole injection layer 41 and the hole transport layer 43 of the intermediate layer 40 are provided on the anode 35. On the other hand, the electron transport layer 47 and the light emitting layer 45 are provided on the cathode 29 and the planarizing layer 25 of the first substrate unit 20. The first substrate unit 20 and the second substrate unit 30 are bonded by causing the light emitting layer 45 provided on the first substrate unit 20 to contact the hole transport layer 43 provided on the second substrate unit 30 side.

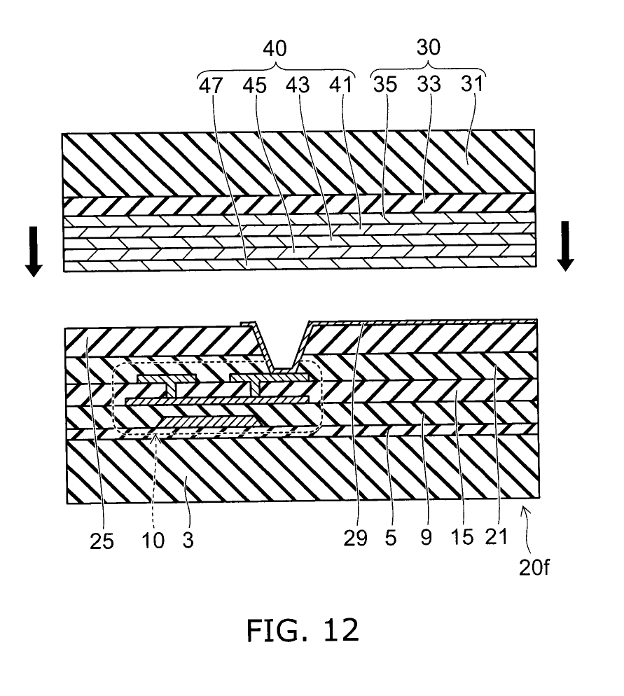

FIG. 12 is a schematic cross-sectional view showing a method for manufacturing the display device according to a sixth modification of the first embodiment. In this modification, the intermediate layer 40 is provided on the anode 35 of the second substrate unit 30. The first substrate unit 20 and the second substrate unit 30 are bonded by causing the cathode 29 of the first substrate unit 20 to contact the electron transport layer 47 provided on the second substrate unit 30 side.

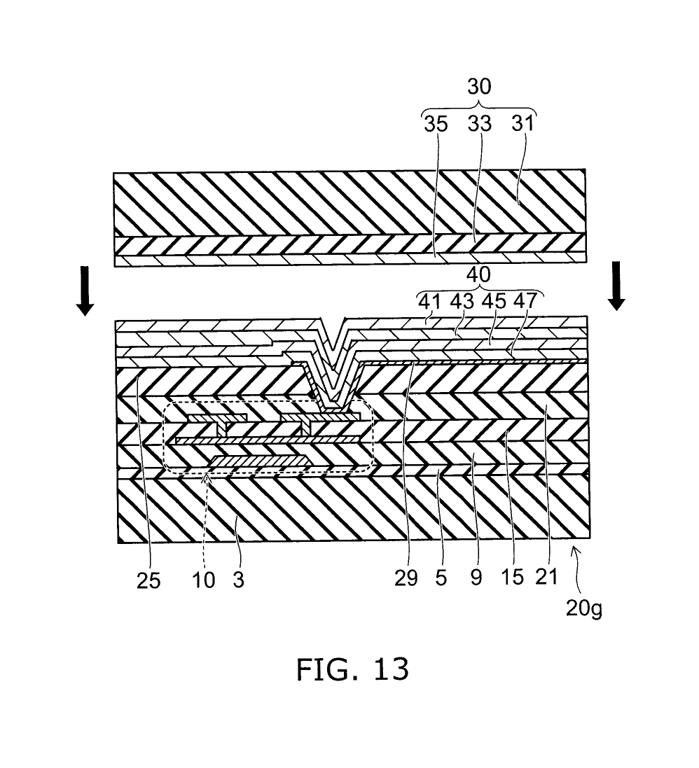

FIG. 13 is a schematic cross-sectional view showing a method for manufacturing the display device according to a seventh modification of the first embodiment. In this modification, the intermediate layer 40 is provided on the cathode 29 of the first substrate unit 20. The first substrate unit 20 and the second substrate unit 30 are bonded by causing the hole injection layer 41 provided on the first substrate unit 20 side to contact the anode 35 of the second substrate unit 30.

The embodiment is not limited to the modifications shown in FIG. 7 to FIG. 13. Any layer of the intermediate layer 40 excluding the light emitting layer 45 may be subdivided, provided on the first substrate unit 20 and the second substrate unit 30, and bonded.

To bond uniformly over the entire surface, it is desirable for at least one selected from the layers at the bonding interface to be thick. However, there are cases where the luminous efficiency of the intermediate layer 40 decreases when the film thickness is greater than necessary because the resistance of the layer increases. Therefore, by performing doping of the layer on at least one side of the bonding interface, the mobility increases; and uniform bonding can be realized while maintaining the efficiency of the intermediate layer 40.

### Second Embodiment

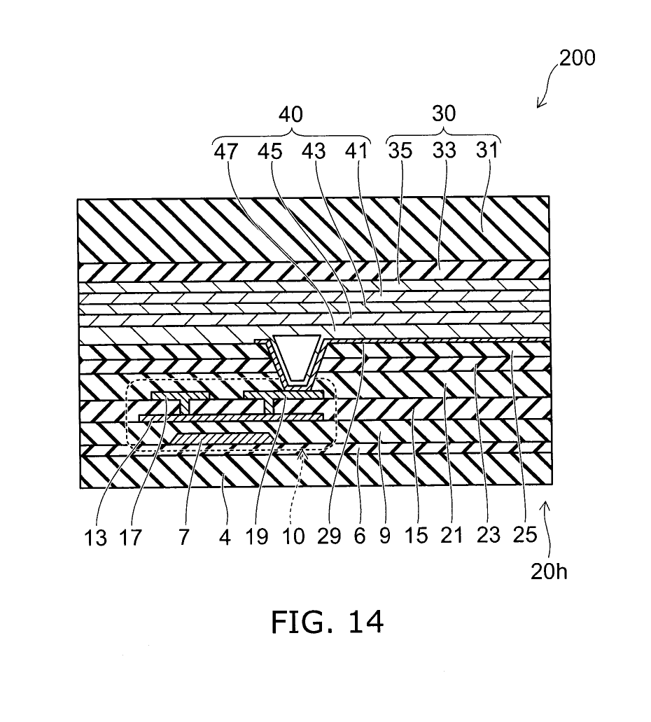

FIG. 14 is a schematic cross-sectional view showing a display device 200 according to a second embodiment.

FIGS. 15A and 15B are schematic cross-sectional views showing a portion of the display device 200 according to the second embodiment.

As shown in FIG. 14, the display device 200 according to the embodiment includes the first substrate unit 20h, the second substrate unit 30, and the intermediate layer 40.

The first substrate unit 20h includes a resin layer 4, a barrier layer 6 provided on the resin layer 4, the n-channel thin film transistor 10 provided on the barrier layer 6, and the cathode 29 connected to the thin film transistor.

The second substrate unit 30 includes the second substrate 31, and the anode 35 provided on the second substrate 31. The second substrate 31 according to the embodiment is a flexible substrate, e.g., a plastic substrate.

In the manufacturing processes of the display device 200, the first substrate unit 20h is caused to oppose the second substrate unit 30 with the intermediate layer 40 interposed. Then, the first substrate unit 20h and the second substrate unit 30 are bonded with the intermediate layer 40 interposed between the cathode 29 and the anode 35.

The resin layer 4 and the barrier layer 6 are formed on the not-shown first substrate 3 on the first substrate unit 20h side. The resin layer 4 may include, for example, an acrylic resin, an epoxy resin, polyimide, aramid, a cycloolefin polymer, etc. For example, the resin layer 4 may be formed by coating polyimide having a high thermal stability onto the first substrate 3 and baking at 400° C. The thickness of the resin layer 4 is, for example, 1 to 10 μm.

Then, the barrier layer 6 is formed by, for example, plasma CVD (Chemical Vapor Deposition), sputtering, or ALD (Atomic-layer Deposition). The barrier layer has a single layer or stacked structure of a silicon oxide film, a silicon nitride film, a silicon oxynitride film, and/or alumina.

Continuing, a not-shown through-hole is made by patterning a resist by lithography and etching the barrier layer 6 by RIE (Reactive Ion Etching). Although the resin layer 4 also is dug into at this time, the depth is controlled by adjusting the etching time. For example, to provide the interconnect connection, and from the aspect of the etching control, it is desirable for the size of the through-hole to be not less than 100 nm. From the aspect of the fixation of the flexible printed circuit board described below, it is desirable to be not more than 20 nm.

Then, the gate electrode 7 of the thin film transistor 10 and the through-electrode that fills the interior of the through-hole are formed. It is also possible to form the gate electrode 7 and the through-electrode separately.

Continuing, the thin film transistor 10 is completed by forming the gate insulating film 9, the channel layer 13, and the source/drain electrodes. After forming the color filter layer 23, the planarizing layer 25, and the cathode 29, the first substrate unit 20h and the second substrate unit 30 are bonded by any of the methods illustrated in the first embodiment.

It is possible to input a signal from the outside by connecting a flexible printed circuit board FPC by using an ACF, etc.

Then, the first substrate 3 that is on the first substrate unit 20h side is peeled from the resin layer 4. For example, mechanical separation at the interface between the first substrate 3, which is a glass substrate, and the resin layer 4 is performed by controlling the adhesion strength between the first substrate 3 and the resin layer 4. Or, the first substrate 3 may be peeled from the resin layer 4 by irradiating light, e.g., an ultraviolet excimer laser, that passes through the glass from the glass substrate side to be absorbed by the resin layer. Thereby, a flexible display can be manufactured.

### Third Embodiment

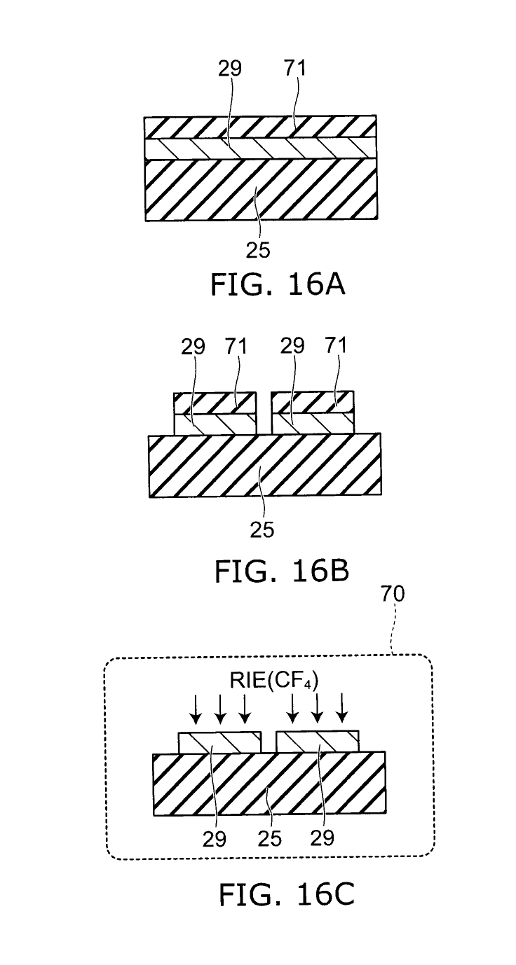

FIG. 16A to FIG. 16C are schematic cross-sectional views showing a method for manufacturing a display device according to a third embodiment. The embodiment illustrates a method for patterning the cathode 29 of the first substrate unit 20.

As shown in FIG. 16A, the cathode 29 is formed on the planarizing layer 25; and a cap layer 71 is formed on the cathode 29. The cap layer 71 is, for example, a silicon nitride film. It is desirable for the cathode 29 and the cap layer 71 to be formed continuously in a reduced oxygen atmosphere, e.g., a vacuum.

Continuing as shown in FIG. 16B, for example, dry etching of the cap layer 71 and the cathode 29 is performed using an etching mask formed by photolithography.

Then, as shown in FIG. 16C, the first substrate unit 20 is transferred into the interior of a chamber 70; and, for example, the interior of the chamber 70 is depressurized. Continuing, the cap layer 71 is removed by RIE using CF₄; and, for example, the electron transport layer 47 is formed on the cathode 29 by moving the first substrate unit 20 into a vapor deposition chamber without being exposed to ambient air. The first substrate unit 20 may be bonded to the second substrate unit 30 with the intermediate layer 40 interposed. Thereby, the surface of the cathode 29 can be connected to the electron transport layer 47 without oxidizing the surface of the cathode 29.

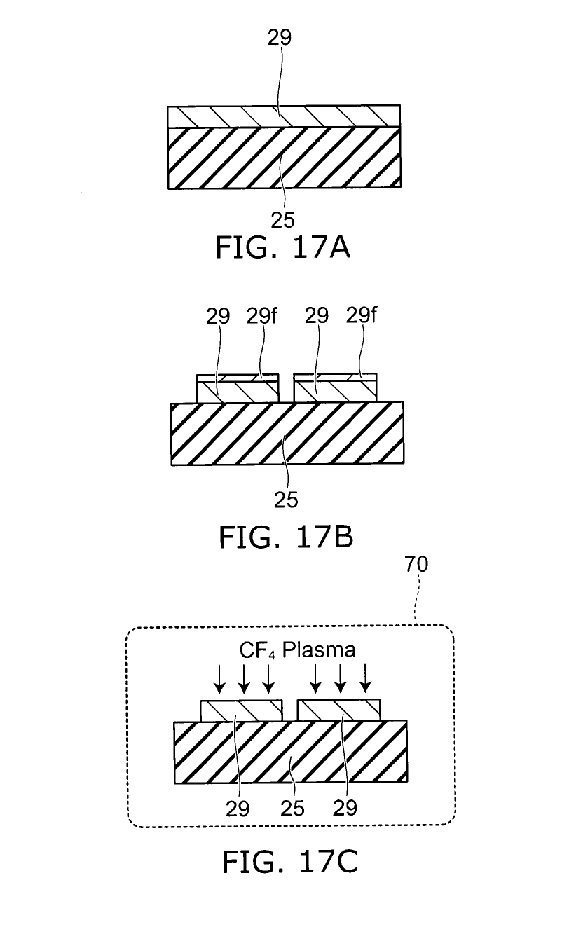

FIG. 17A to FIG. 17C are schematic cross-sectional views showing a method for manufacturing the display device according to a first modification of the third embodiment.

As shown in FIG. 17A, the cathode 29 is formed on the planarizing layer 25.

Continuing as shown in FIG. 17B, for example, wet etching of the cathode 29 is performed using an etching mask formed by photolithography. At this time, an oxide layer 29f is formed on the surface of the cathode 29.

Then, as shown in FIG. 17C, the first substrate unit 20 is transferred into the interior of the chamber 70; and, for example, the interior of the chamber 70 is depressurized. Continuing, the oxide layer 29f is removed by exposing the cathode 29 to plasma formed by exciting CF₄. Continuing, for example, the electron transport layer 47 is formed on the cathode 29. The first substrate unit 20 may be bonded to the second substrate unit 30 with the intermediate layer 40 interposed. It is desirable to implement the bonding by transferring the first substrate unit 20 into another chamber in a reduced oxygen atmosphere after the removal of the oxide layer 29f. Thereby, the cathode 29 and the electron transport layer 47 can be connected without the oxide layer 29f being interposed.

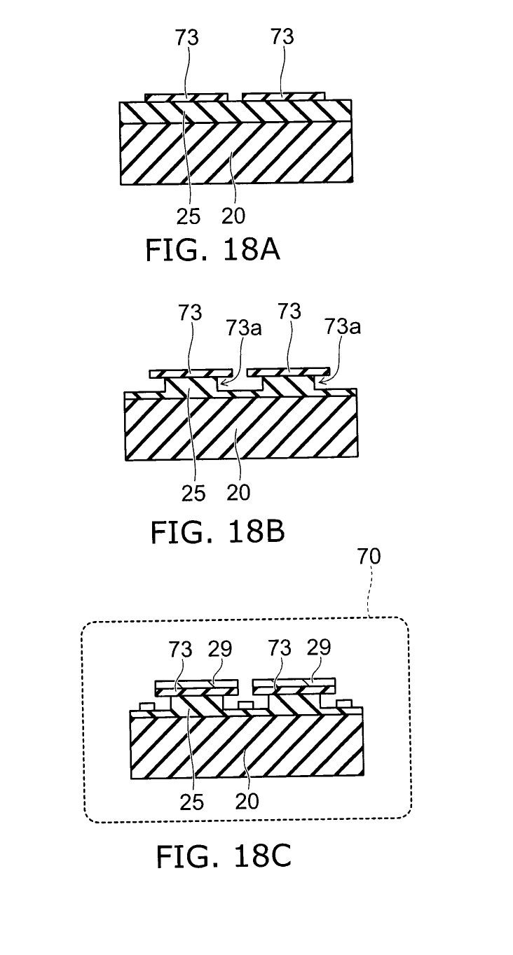

FIGS. 18A to 18C are schematic cross-sectional views showing a method for manufacturing the display device according to a second modification of the third embodiment.

As shown in FIG. 18A, a spacer film 73 is selectively formed on the planarizing layer 25. The spacer film 73 is, for example, a silicon oxide film.

Continuing as shown in FIG. 18B, an undercut portion 73a is made by etching the planarizing layer 25 using the spacer film 73 as a mask. The etching may be, for example, dry etching such as RIE (Reactive Ion Etching), ashing, CDE (Chemical Dry Etching), etc.

Then, as shown in FIG. 18C, the first substrate unit 20 is transferred into the interior of the chamber 70; and, for example, the interior of the chamber 70 is depressurized. Continuing, a MgAg film used to form the cathode 29 is vapor-deposited. At this time, the MgAg film is separated by the undercut portion 73a; and the cathode 29 is formed on the spacer film 73.

Continuing, the electron transport layer 47 is formed on the cathode 29. The first substrate unit 20 may be bonded to the second substrate unit 30 with the intermediate layer 40 interposed. It is desirable to implement the bonding by transferring the first substrate unit 20 to another chamber in a vacuum or reduced oxygen atmosphere. Thereby, the cathode 29 can be connected to the electron transport layer 47 with suppressed oxidization of the cathode 29.

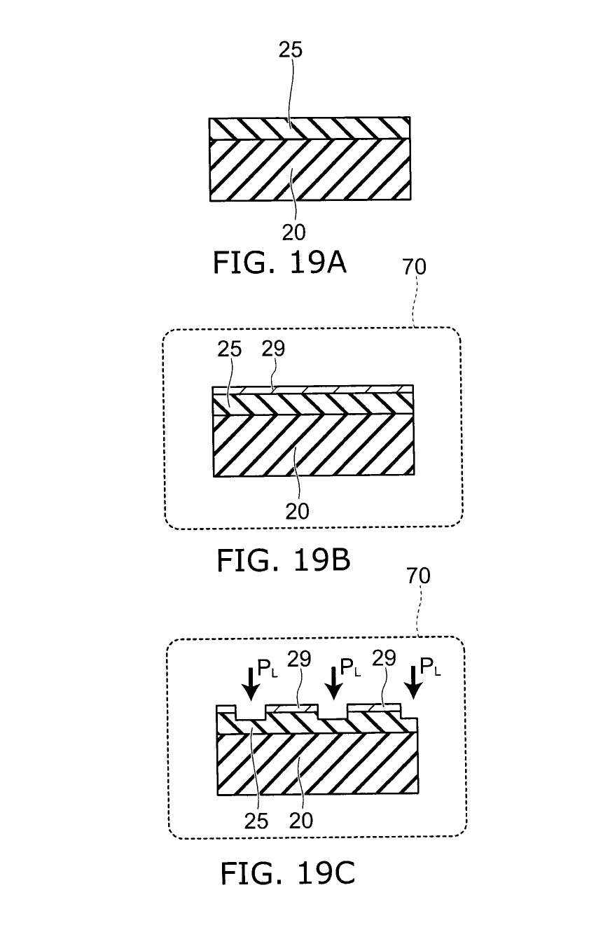

FIGS. 19A to 19C are schematic cross-sectional views showing a method for manufacturing the display device according to a third modification of the third embodiment.

As shown in FIG. 19A, a first substrate unit 20 in which the layers up to the planarizing layer 25 are formed is prepared.

Then, as shown in FIG. 19B, the first substrate unit 20 is transferred into the interior of the chamber 70; and, for example, the interior of the chamber 70 is depressurized. Continuing, a metal film used to form the cathode 29, e.g., MgAg, is vapor-deposited.

Continuing, the metal film is selectively removed by irradiating laser light. A short pulse laser is suitable as the laser used in this process; and the patterning of the metal film is possible by laser light having a pulse width of femtoseconds or picoseconds.

Then, the electron transport layer 47 is formed on the cathode 29 that is formed by patterning the metal film. The first substrate unit 20 may be bonded to the second substrate unit 30 with the intermediate layer 40 interposed. It is desirable to implement these processes after forming the electron transport layer 47 by transferring the first substrate unit 20 into another chamber in a vacuum or reduced oxygen atmosphere. Thereby, the cathode 29 can be connected to the electron transport layer 47 with suppressed oxidization of the cathode 29.

### Fourth Embodiment

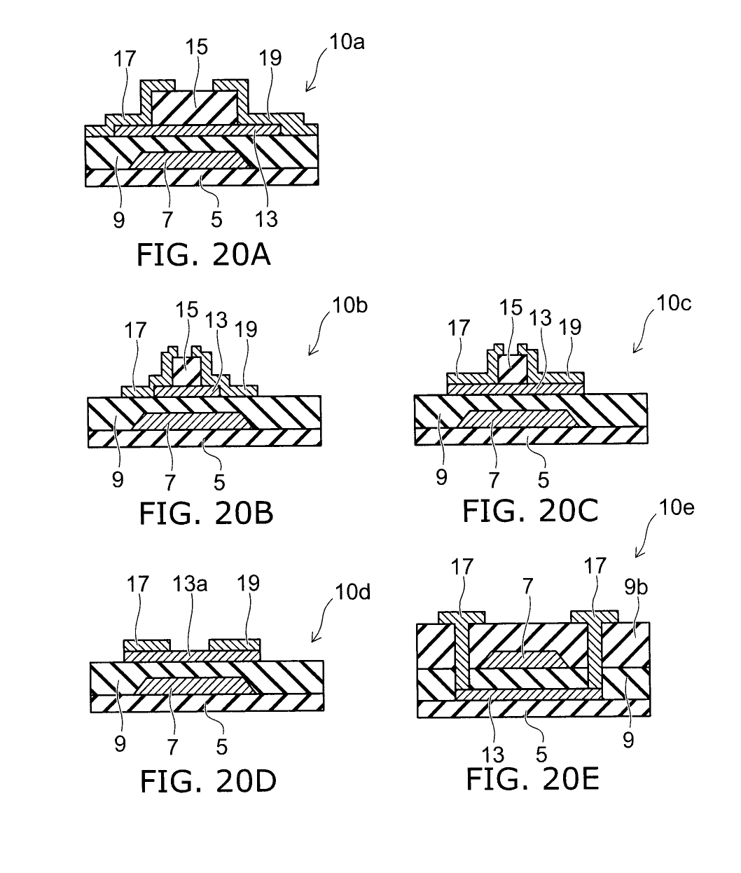

FIG. 20A to FIG. 20E are schematic cross-sectional views showing portions of display devices according to a fourth embodiment. FIG. 20A to FIG. 20E show thin film transistors 10a to 10e, respectively.

As shown in FIG. 20A, it is also possible to use the thin film transistor 10a using a self-aligned channel protection layer using back exposure. The channel layer may include IGZO or a-Si:H (the n⁺ layer for the contacts is not shown).

In the thin film transistor 10b shown in FIG. 20B, the channel length is shorter than that of the thin film transistor 10a of FIG. 20A; and the channel layer 13 is completely within the upper portion of the gate electrode.

As in the thin film transistor 10c shown in FIG. 20C, a structure in which the source-drain electrodes and the channel layer are simultaneously etched also is applicable.

In the thin film transistor 10d shown in FIG. 20D, the channel protection layer 15 is not provided between the source electrode 17 and the drain electrode 19. Thus, a back-channel cut may be used. The channel layer 13 may include IGZO or a-Si:H in which an n⁺ layer (not shown) is formed.

The thin film transistor 10e shown in FIG. 20E is a top-gate TFT. The channel layer 13 is provided on the undercoat layer 5; and the gate electrode 7 is provided on the gate insulating film 9 that covers the channel layer 13. The source electrode 17 and the drain electrode 19 are provided on an insulating film 9b that covers the gate electrode 7 and are connected to the channel layer 13 by piercing the insulating film 9b and the gate insulating film 9.

An oxide TFT using polysilicon, IGZO, etc., may be used as the thin film transistor 10.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A method for manufacturing a display device, comprising:
disposing a cathode of a first substrate unit to face an anode of a second substrate unit with an intermediate layer interposed, the first substrate unit including a first substrate, a thin film transistor provided on the first substrate, and the cathode connected to the thin film transistor, the thin film transistor being an n-channel thin film transistor, the second substrate unit including a second substrate and the anode provided on the second substrate; and
bonding the cathode to the anode with the intermediate layer interposed.

2. The method according to claim 1, wherein the intermediate layer is provided on the anode.

3. The method according to claim 1, wherein the intermediate layer is provided on the cathode.

4. The method according to claim 1, wherein
one portion of the intermediate layer is provided on the cathode,
the other portion of the intermediate layer is provided on the anode, and
the bonding includes connecting the one portion of the intermediate layer and the other portion of the intermediate layer to each other.

5. The method according to claim 1, wherein
the intermediate layer includes a first layer and a light emitting layer,
the light emitting layer and one portion of the first layer are provided on the cathode,
the other portion of the first layer is provided on the anode, and
the bonding includes connecting the one portion of the first layer and the other portion of the first layer to each other.

6. The method according to claim 1, wherein
the intermediate layer includes a first layer and a light emitting layer,
one portion of the first layer is provided on the cathode,
the light emitting layer and the other portion of the first layer are provided on the anode, and
the bonding includes connecting the one portion of the first layer and the other portion of the first layer to each other.

7. The method according to claim 5, wherein the first layer is an electron transport layer.

8. The method according to claim 1, wherein
the thin film transistor includes a contact portion connected to the cathode, and
the first substrate unit further includes a protective layer provided on the first substrate to cover the thin film transistor except for the contact portion.

9. The method according to claim 1, wherein
the thin film transistor includes a contact portion connected to the cathode, and
the first substrate unit further includes a color filter layer provided on the first substrate to cover the thin film transistor except for the contact portion.

10. The method according to claim 1, wherein the bonding is implemented in a reduced oxygen atmosphere.

11. The method according to claim 10, wherein the bonding is implemented in the reduced oxygen atmosphere in which the cathode is formed or exposed.

12. A display device, comprising:
an anode;
an intermediate layer including a hole transport layer, a light emitting layer, and an electron transport layer, the light emitting layer being provided between the hole transport layer and the electron transport layer;
a cathode bonded to the anode with the intermediate layer interposed; and
a thin film transistor connected to the cathode, the thin film transistor being an n-channel thin film transistor.

13. The device according to claim 12, wherein
the cathode has a first portion contacting the electron transport layer, and a second portion contacting a drain contact portion of the thin film transistor, and
a spacing between the light emitting layer and the first portion is less than a spacing between the light emitting layer and the second portion.

14. The device according to claim 13, wherein the second portion and the light emitting layer define a space including a gas between the second portion and the light emitting layer.

15. The device according to claim 12, wherein the anode is connected to the hole transport layer with a hole injection layer interposed.

16. The device according to claim 12, further comprising:
a first substrate on which the cathode and the thin film transistor is provided; and
a second substrate on which the anode is provided.

17. The device according to claim 16 further comprising a color filter,
wherein the thin film transistor and the color filter are provided on the first substrate, and
the cathode is provided on the color filter.

18. The device according to claim 16 further comprising a
reflecting electrode,
wherein the reflecting electrode is provided on the second substrate, and the anode is provided on the reflecting electrode.

19. The device according to claim 18 further comprising a barrier layer between the second substrate and the reflecting electrode.

20. The device according to claim 16, further comprising a connection unit electrically connecting the first substrate unit to the second substrate unit.
